(19) United States
(12) Patent Application Publication
(10) Pub. No.: US 2012/0024343 A1
(43) Pub. Date: Feb. 2, 2012

(54) Method and Structure for a Cool Roof by Using a Plenum Structure

(75) Inventor: Ramachandran Narayanamurthy, El Cerrito, CA (US)

(73) Assignee: PVT Solar, Inc., Berkeley, CA (US)

(21) Appl. No.: 12/794,352

(22) Filed: Jun. 4, 2010

Related U.S. Application Data
(60) Provisional application No. 61/185,990, filed on Jun. 10, 2009.

(51) Int. Cl. H01L 31/052; E04D 13/18; F24F 7/02

(52) U.S. Cl. 136/246; 165/47; 126/632

(57) ABSTRACT

A method for providing a cool roof by processing fluid within a vicinity of a roof structure having a surface area includes transferring a volume of air with a selected flow rate through a plenum structure disposed underlying one or more solar modules and coupled to the roof structure spatially over a height above a portion of the surface area. Each of the one or more solar modules is coupled to each other. The plenum structure has at least an intake region and an exit region for the volume of air. The method additionally includes maintaining a roof temperature profile for the portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

### CROSS-REFERENCE TO RELATED APPLICATION

This application claims priority to U.S. Provisional Patent Application No. 61/185,990, filed Jun. 10, 2009, entitled “A METHOD AND STRUCTURE FOR A COOL ROOF BY USING A PLENUM STRUCTURE” by inventor Ramachandran Narayanamurthy, commonly assigned and incorporated by reference herein for all purposes.

### BACKGROUND OF THE INVENTION

This invention relates to operation of thermal solar system. More particularly, the invention provides a method and structure for cooling a roof by using a plenum structure associated with a thermal solar system. The invention has been applied to a thermal solar module configured on a building structure, but it would be recognized that the invention has a much broader range of applications.

Over the past centuries, the world population of human beings has exploded. Along with the population, demand for resources has also grown explosively. Such resources include raw materials such as wood, iron, and copper and energy, including coal and oil. Industrial countries worldwide project more increases in oil consumption for transportation and heating purposes, especially from developing nations such as China and India. Obviously, our daily lives depend, for the most part, upon oil or other fossil fuels, which are being depleted and becoming increasingly scarce.

Along with the depletion of our fossil fuel resources, our planet has experienced a global warming phenomena, recently brought to our foremost attention by Al Gore, the former Vice President of the United States of America. Global warming is an increase in the average temperature of the Earth's air near its surface, which is projected to continue to increase. This warming is believed to be caused by greenhouse gases, which are derived, in part, from use of fossil fuels. The increase in temperature is expected to cause extreme weather conditions and a reduction of the polar ice caps, which in turn will lead to higher sea levels and an increase in the rate of warming. Ultimately, other effects include mass species extinctions, and other uncertainties possibly detrimental to human beings.

Much if not all of the useful energy found on the Earth comes from our sun. Generally all common plant life on the Earth achieves life using photosynthesis processes from sun light. Fossil fuels such as oil were also developed from biological materials derived from energy associated with the sun. For most living beings on the Earth, sunlight has been essential. Likewise, the sun has been our most important energy source and fuel for modern day solar energy. Solar energy possesses many characteristics that are very desirable! Solar energy is renewable, clean, abundant, and often readily available.

Solar panels have been developed to convert sunlight into energy. For example, solar thermal panels often convert electromagnetic radiation from the sun into thermal energy for heating homes, running industrial processes, or driving turbines to generate electricity. As another example, solar photovoltaic panels convert sunlight directly into electricity for a variety of applications. Solar panels are generally composed of an array of solar cells, which are interconnected to each other. The cells are usually arranged in series and/or parallel groups. Solar panels have great potential to benefit our nation, security, and human users. They can even diversify our energy demands and reduce the world's dependence on oil and other potentially detrimental sources of energy.

Although solar panels have been used successful for certain applications, there are still certain limitations. Solar cells are often costly. Depending upon the geographic region, there may be financial subsidies from governmental entities for purchasing solar panels, which otherwise might not be cost competitive with the direct purchase of electricity from public power companies. Additionally, the panels are often composed of silicon bearing wafer materials. Such wafer materials can be costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification.

From the above, it is seen that techniques for improving operation of a solar related systems are desired.

### BRIEF SUMMARY OF THE INVENTION

The present invention relates to thermal solar heating systems. More particularly, the present invention provides a method and structure for cooling a roof by using a plenum structure associated with a thermal solar system. The invention can be applied to a thermal solar module configured on a building structure, as well as other applications.

In a specific embodiment, the present invention provides a method for providing a cooler roof by processing fluid within a vicinity of a roof structure. The method includes providing a roof structure having a surface area. Additionally, the method includes transferring a volume of air with a selected flow rate through a plenum structure disposed underlying one or more solar modules and coupled to the roof structure spatially over a height above a portion of the surface area. The roof structure can be a selected color such as white, silver, yellow, or other colors capable of reflecting electromagnetic radiation in a solar spectrum. Each of the one or more solar modules is coupled to each other. The plenum structure has an intake region and an exit region for the volume of air. Moreover, the method includes maintaining a roof temperature profile for the portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

In another specific embodiment, the present invention provides a system for providing a roof maintained within a predetermined temperature range by processing fluid within a vicinity of a roof structure, The system includes a roof structure having a surface area and a plenum structure configured for transferring a volume of air within a selected flow rate. The plenum structure is disposed underlying one or more solar modules and coupled to the roof structure spatially over a height above a portion of the surface area. Each of the one or more solar modules is coupled to each other. The plenum structure has at least an intake region and an exit region for the volume of air. Additionally, the system includes a roof temperature profile configured within the portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

In an alternative embodiment, the present invention provides a system for providing a roof maintained within a predetermined temperature range by processing fluid within a vicinity of a roof structure. The system includes a plenum structure configured for transferring a volume of air within a selected flow rate. The plenum structure is coupled to a roof structure spatially over a height above a portion of a surface area of the roof structure. The plenum structure has at least an intake region and an exit region for the volume of air. Additionally, the system includes a roof temperature profile configured within the portion of the surface area starting from the intake region to the exit region for a predetermined amount of time using at least the flow rate of the volume of air being transported through the plenum structure. The roof temperature profile is configured by a first temperature value substantially equal to an ambient air temperature at the intake region to a second temperature value in the vicinity of the exit region depending on the flow rate and substantially smaller than a temperature of bare roof structure outside the portion of the surface area.

In yet another alternative embodiment, the present invention provides a method for providing a roof within a predetermined temperature range by processing fluid within a vicinity of a roof structure. The method includes transferring a volume of air with a selected flow rate through a plenum structure coupled to a roof structure spatially over a height above a portion of the surface area of the roof structure. The plenum structure has at least an intake region and an exit region for the volume of air. Additionally, the method includes maintaining a roof temperature profile for the portion of the surface area starting from the intake region to the exit region for a predetermined amount of time using at least the flow rate of the volume of air being transported through the plenum structure. The roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

In a specific embodiment, the roof temperature profile within the portion of the surface area comprises an average temperature no greater than about 105 degrees Fahrenheit on a day with 90 degrees Fahrenheit ambient air temperature. In another specific embodiment, the second temperature value is a less than 20 degrees Fahrenheit above the first temperature value. In yet another specific embodiment, the method further includes emitting infrared radiation from the roof structure or plenum structure. In yet still another specific embodiment, the roof structure is white in color.

In yet another specific embodiment, the present invention provides a method for providing a cool roof by processing fluid within a vicinity of a roof structure. The method includes providing a roof structure having a surface area. Additionally, the method includes maintaining a temperature profile for a portion of the surface area starting from an intake region to an exit region for a predetermined amount of time using at least a flow rate of a volume of air being transported through a plenum structure configured within a vicinity of the portion of the surface area.

In yet still another specific embodiment, the present invention provides a thermal solar system for providing a roof maintained within a predetermined temperature range. The system includes a plenum structure configured for transferring a volume of air within a flow rate. The plenum structure is coupled to a surface region of a roof structure. Additionally, the system includes a temperature profile configured within the portion of the surface area starting from a first region to a second region of the plenum structure for a predetermined amount of time using at least the flow rate of the volume of air being transported through the plenum structure.

As used herein, the term “cool roof” should be interpreted by ordinary meaning understood by someone of ordinary skill in the art. As an example, the term cool roof has been defined by the California Energy Commission and other entities. See also, for example, http://en.wikipedia.org/wiki/Cool_roof.
In the world of industrial and commercial buildings, a roofing system that can deliver high solar reflectance (the ability to reflect the visible, infrared and ultraviolet wavelengths of the sun, reducing heat transfer to the building) and high thermal emittance (the ability to release a large percentage of absorbed, or non-reflected solar energy) is a cool roof. Most cool roofs are white or other light colors.
In tropical Australia, zinc-galvanized (silvery) sheeting (usually corrugated) reflect heat much better than the “cool” color of white. European fashion trends are now using darker-colored aluminium roofing, to pursue consumer fashions.
Cool roofs enhance roof durability and reduce both building cooling loads and the urban heat island effect.
Also known as albedo, solar reflectance is expressed either as a decimal fraction or a percentage. A value of 0 indicates that the surface absorbs all solar radiation, and a value of 1 represents total reflectivity. Thermal emittance is also expressed either as a decimal fraction between 0 and 1, or a percentage. A newer method of evaluating coolness is the solar reflectance index (SRI), which incorporates both solar reflectance and emittance in a single value. SRI quantifies how hot a surface would get relative to standard black and standard white surfaces. It is defined such that a standard black (reflectance 0.05, emittance 0.90) is 0 and a standard white (reflectance 0.80, emittance 0.90) is 100.
Cool roofs are an effective alternative to bulk attic insulation under roofs in humid tropical and subtropical climates. Bulk insulation can be entirely replaced by roofing systems that both reflect solar radiation and provide emission to the sky. This dual function is crucial, and relies on the performance of cool roof materials in both the visible spectrum (which needs to be reflected) and far infra-red which needs to be emitted.
Cool roof can also be used as a geoengineering technique to tackle global warming based on the principle of solar radiation management, provided that the materials used not only reflect solar energy, but also emit infra-red radiation to cool the planet. This technique can give between 0.01-0.19 W/m2 of globally-averaged negative forcing, depending on whether cities or all settlements are so treated. This is generally small when compared to the 3.7 W/m2 of positive forcing from a doubling of CO2. However, in many cases it can be achieved at little or no cost by simply selecting different materials. Further, it can reduce the need for air conditioning, which causes CO2 emissions which worsen global warming. For this reason alone it is still demonstrably worth pursuing as a geoengineering technique.

In other examples, cool roofs have been rated by Energy Star, which is a joint program of the U.S. Environmental Protection Agency and the U.S. Department of Energy designed to reduce greenhouse gas emissions and help businesses and consumers save money by making energy-efficient product choices. Additionally, Cool Roof Rating Council (CRRC) has also created a rating system for measuring and reporting the solar reflectance and thermal emittance of roofing products. Other entities include, but are not limited to, the Green Globes system, which is used in Canada and the United States. Other examples include LEED, among others. See also, Consumer Energy Center. Of course, there can be other variations, modifications, and alternatives.

Many benefits are achieved by way of the present invention over conventional techniques. For example, the present technique provides an easy to use process that relies upon conventional technologies such as thin film photovoltaic modules, which can be configured as a thermal solar device. Additionally, the present method provides a process that is compatible with the conventional photovoltaic module without substantial modifications to equipment and processes. Preferably, the invention provides for an improved solar module operation procedure, which is less costly and easy to handle, and has both electrical and thermal energy generation and utilization. In a specific embodiment, the present method and system provides for control of photovoltaic and thermal solar operation. Depending upon the embodiment, thermal energy in the form of heat can be used to improve efficiency of the thin film photovoltaic cell according to an embodiment of the present invention. In other embodiments, the present invention provides a method and structure having an improved efficiency per area of at least 10 percent and greater or 25 percent and greater using a thin film photovoltaic absorber depending upon the application. In a specific embodiment, the present improved efficiency is for a thin film based photovoltaic material, which traditionally has lower efficiencies. In a preferred embodiment, the overall energy conversion efficiency of the thermal solar system, including both thermal solar module and photovoltaic device using a thin film photovoltaic material, can be greater than about 30 percent. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram of a thermal solar system disposed on a roof structure according to an embodiment of the present invention.

FIG. 2 is a simplified side view diagram of a plenum structure for cooling roof according to an embodiment of the present invention.

FIG. 2A is a schematic side view diagram of a plenum structure according to an embodiment of the present invention.

FIG. 2B is a simplified perspective view diagram of a plenum structure mounted on a roof of a building structure according to an embodiment of the present invention.

FIG. 3A is a simplified view of a section of dark roof versus a section of white roof in ambient air under the sun.

FIG. 3B is a simplified view of the dark roof and the white roof each with a PV panel installed.

FIG. 3C is a simplified view of the dark roof and the white roof each having a PVT panel with a plenum structure installed according to an embodiment of the present invention.

FIG. 4A shows simplified roof temperature profiles for dark roof with and without PVT plenum structure according to an embodiment of the present invention.

FIG. 4B shows simplified roof temperature profiles for white roof with and without PVT plenum structure according to an embodiment of the present invention.

FIG. 4C shows simplified roof temperature profiles of a cool roof plenum structure respectively with high and low air flow rate according to an embodiment of the present invention.

### DETAILED DESCRIPTION OF THE INVENTION

The present invention relates to operation of thermal solar system. More particularly, the present invention provides a method and structure for cooling roof by using a plenum structure associating a thermal solar system. Merely, by way of example, the present invention has been applied to a thermal solar module configured on a building structure, but it would be recognized that the invention has a much broader range of applications.

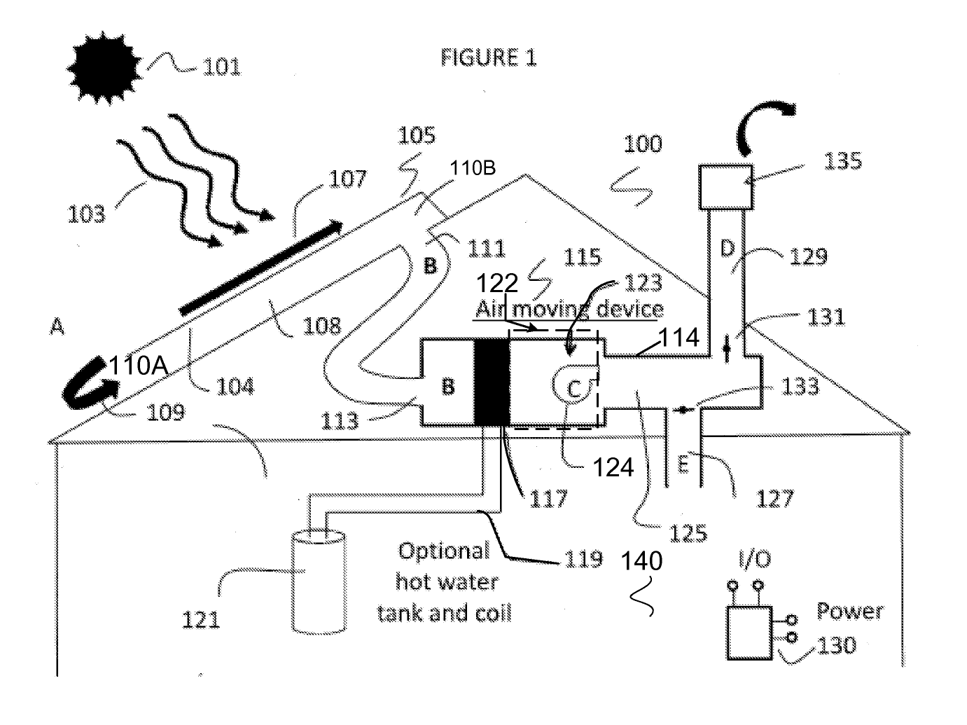

FIG. 1 is a simplified side view diagram of a thermal solar system according to an embodiment of the present invention. This diagram is merely an example, which should not unduly limit the scope of the claims herein. One of ordinary skill in the art would recognize other variations, modifications, and alternatives. As shown, the thermal solar system 100 includes a plurality of thermal modules spatially configured as an N by M array, where N is an integer equal to or greater than 1, and M is an integer greater than 2 spatially disposed and attached to a spatial face of a building structure. The spatial face can be a roof, building side, rack, or the like. In a specific embodiment, the plurality of thermal modules is configured to form an aperture region 105 and a backside region 104. In one or more embodiments, the thermal solar modules can be combined with photovoltaic modules or solely thermal modules or photovoltaic modules configured for thermal use to provide a heat source. Of course, there can be other variations, modifications, and alternatives.

In a specific embodiment, electromagnetic radiation 103 from the sun or other radiation source illuminates on the aperture region 105. In one or more embodiments, thermal energy is transferred through the plurality of thermal modules so that the thermal energy is applied to a working fluid 109 such as air, which traverses 107 is an upward direction through a plenum structure 108 configured from at least the backside region 104. In a specific embodiment, the plenum structure 108 has one or more intake regions 110A and one or more exhaust regions 110B. The plenum structure 108 is a substantially closed physical enclosure of a volume including the one ore intake regions 110A and the one or more exhaust regions 110B. For example, the one or more intake regions 110A can be configured near a lower portion of the plurality of thermal modules to draw colder working fluid 109 (for example air from outside), although there can be other spatial locations. Additionally, the one or more exhaust regions 110B can be a single exhaust region or multiple exhaust regions disposed spatially in a configuration near an upper portion of the plurality of thermal modules. Of course, there can be other variations, modifications, and alternatives.

Referring again to FIG. 1, the thermal solar system has a first duct 111 coupled to the one or more exhaust regions 110B. In a specific embodiment, the first duct 111 can couple into a thermal transfer module 115 having a fluid flow intake region 113 coupled to the first duct 111, a fluid flow exit region 125 coupled via a second duct 114, and a fluid drive region 123 spatially disposed between the fluid flow intake region 113 and the fluid flow exit region 125. As used herein, the terms “fluid exit region”, “fluid flow intake region”, “fluid drive region” and others are not intended to be limiting and should be interpreted by ordinary meaning Also shown are valves or dampers 131, 133 which respectively connect to one or more air pathways 129, 133 to an outside region via exhaust 135 or back into the building structure via exhaust 127. Of course, there can be other variations, modifications, and alternatives.

In a specific embodiment, the thermal transfer module 115 has an air moving device 122 comprising a drive device 124 coupled to a blower device (not being detailed explicitly). In a preferred embodiment, the drive device 124 is spatially disposed within the fluid drive region 123. In a specific embodiment, the drive device 124 comprises an electric motor with high temperature windings which can withstand about 165 degrees F. As merely an example, the electric motor is a Class F and greater under the trade association for the Association of Electrical and Medical Imaging Equipment Manufacturers, commonly called “NEMA”. In a specific embodiment, the drive device is operable at a range from about 400 RPM to 4000 RPM, but can be others. In a preferred embodiment, the blower device comprises a fan device having a centrifugal configuration operably coupled to the drive device. Such blower device comprises one or more turbulation elements. In a specific embodiment, the turbulent elements include a plurality of blades, which are configured to move high volumes of fluid and in particular air with a controlled flow rate from the plenum structure 108 through the first duct 110 and subsequently the fluid drive region 123, fluid exit region 125, to one or more exhaust regions 127 and 135. In a preferred embodiment, the fluid flow comprises air flow having temperatures ranging from about 32 degrees Fahrenheit to about 200 degrees Fahrenheit or less based upon the temperature insulation rating of the drive device 124.

In a specific embodiment, the thermal solar system has a controller device 130 coupled to the air moving device 122 for controlling the fluid flow. The controller device 130 couples one or more sensing devices operably coupled to the drive device. In an embodiment, the one or more sensing devices are disposed spatially within a vicinity of the drive device 124. In an implementation, the one or more sensing devices are temperature sensors each comprising a thermocouple or other type of sensing device capable of receiving information that is indicative of temperature (at least taking an analog or a digital signal relative to a specific temperature value) of the drive device 124. As an example, the sensing device can be a snap action bi-metal or the like or others. Of course, there are other variations, modifications, and alternatives.

The thermal solar system 100 is configured to improve the mean time between failures of the drive device 124. As used herein, the term “failure” generally refers to a chronic or catastrophic failure of the drive device, but can have other meanings consistent with ordinary meaning. In a specific embodiment, the drive device is characterized by a life cycle Mean Time Between Chronic Failure MTBF of greater than 20,000 hours for a class of insulation for the drive device. In a specific embodiment, the drive device 124 is characterized by an MTBF of about 10,000 hours and less when the temperature within the fluid drive region 123 exceeds 200 degrees Fahrenheit. Of course, there can be other variations, modifications, and alternatives.

In a specific embodiment, the controller device 130 includes input/output for power, input/output for one or more sensing devices, and input/output for signal control and/or signal feedback. As an example, the controller device 130 can be a computer system, including microprocessor device, memory device, and input/output drivers and the like. As another example, such controller can be one developed by PVT Solar or other suitable companies such as Siemens Programmable Logic Controller, or others. Further detail can be found through out this specification and other variations, modifications, and alternatives are possible.

In an implementation, the controller device 130 is configured to operate the blower device in a first direction to cause fluid flow from at least the fluid flow intake region 113 to the fluid flow exit region 125 and to maintain a fluid (air) temperature of no greater than 200 degrees Fahrenheit within the fluid drive region 123. In a specific embodiment, the air moving device 122 and preferably the drive device is maintained below about 200 degrees Fahrenheit or more preferably below 145 degrees Fahrenheit or more preferably below 125 degrees Fahrenheit, or alternatively, less than 15 degrees Fahrenheit above an ambient air temperature for a particular day, but can be others. The controller device 130 is also configured to send one or more signals to at least change the first direction of fluid flow by controlling the blower device to a second direction to cause fluid flow from a third region to the fluid drive region 123 to initiate removal of thermal energy from the fluid drive region 123. In a specific embodiment, the third region can be from an interior region 140 of the building structure through the exhaust 127 and/or ambient (outer) region of the building structure through exhaust 135. In a preferred embodiment, cool air from the third region traverses back across the drive device 124 to remove thermal energy therefrom to prevent heat-damage to the drive device.

In another specific embodiment, the controller device 130 is also configured to maintain the volume of air within the plenum structure 108 substantially free from a no flow condition for a time period of greater than ½ hours while the fluid flow is changing from the first direction to the second direction mentioned above. In a specific embodiment, the no flow condition occurs for less than one minute. In one or more embodiments, the thermal solar system 100 substantially prevents the no flow condition to maintain the plurality of thermal solar modules free from heat-damage and/or detrimental reliability issues. In a specific embodiment, the no flow condition occurs when the hot air through the plenum structure 108 is substantially free from any air velocity or such air velocity is less than about 2 feet per minute or others. Of course, there can be other variations, modifications, and alternatives.

Referring again to FIG. 1, the second duct 114 is coupled to the fluid exit region 125. In a specific embodiment, the second duct 114 is coupled to the third region mentioned above, which has a temperature of less than 200 degrees Fahrenheit or less than about 125 degrees Fahrenheit or less than about 100 degrees Fahrenheit, but can be others. As shown, the thermal solar system can also include a heat exchanger 117 spatially disposed between one or more regions coupled to the air moving device 122 to capture thermal energy in an efficient manner. The heat exchanger 117 also is configured to reduce the temperature of fluid flow before it traverses over the drive device 124 according to a specific embodiment. As shown, the heat exchanger 117 couples to piping 119, which connects to a water tank 121 for preheating water therein. The water tank 121 can be a conventional water heater modified to include the suitable piping 119 to couple with the heat exchanger 117 to utilize the thermal energy from the thermal solar system for heating the water instead of using traditional gas burner or electrical burner. Of course, other heating or heat storage apparatus can be utilized for the same purpose.

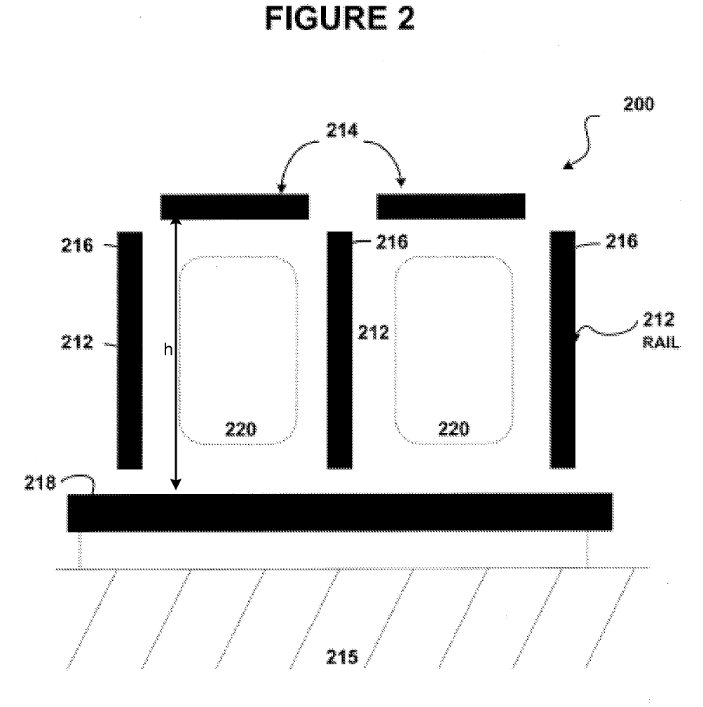

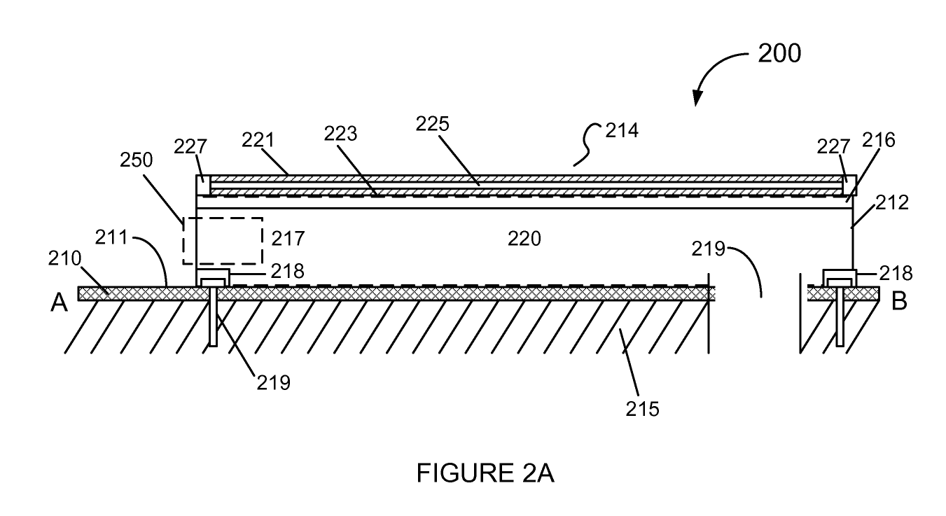

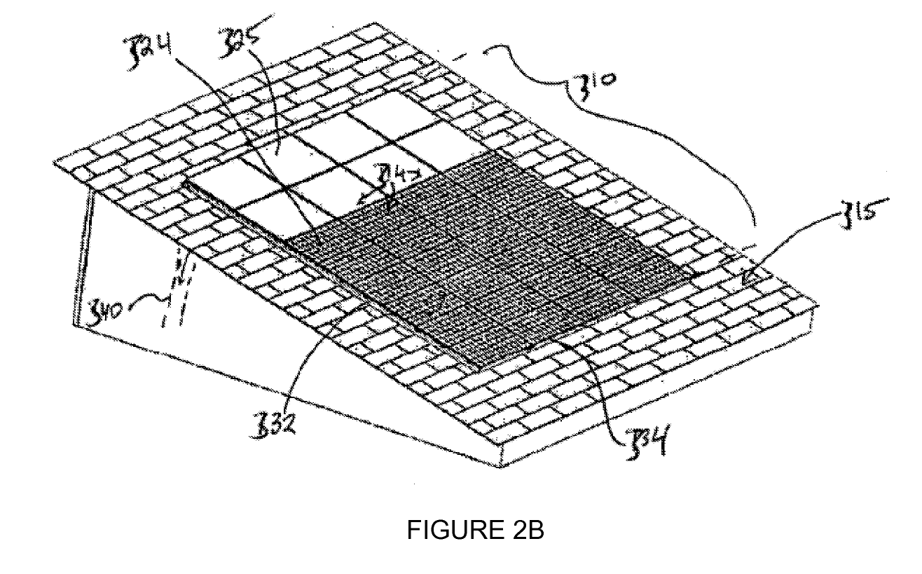

FIG. 2 is a simplified side view diagram of a plenum structure for cooling roof according to an embodiment of the present invention. This diagram is merely an example, which should not unduly limit the scope of the claims herein. One of ordinary skill in the art would recognize other variations, modifications, and alternatives. As shown, the plenum structure 200 is configured to couple/support one or more solar modules 214, under one or more embodiments of the invention. In a specific embodiment, the plenum structure 200 includes an upper region composed of at least a portion of the one or more solar modules 214, which can be interlinked together, a lower region composed of partially the surface area 211 of the roof structure 210, and a rack assembly disposed along the side of the plenum structure, substantially enclosing a volume of space 220. As shown, the rack assembly includes a plurality of rail structures 212 that provide support for each of the one or more solar modules 214. When installed, the rail structures 212 support the individual solar modules 214 a given height h above the surface of the roof structure 210 which has an underlying body 215. The underlying body 215 may correspond to any platform or structure on which the solar modules 214 are mounted. For example, underlying body 215 may correspond to a roof of a commercial or residential building or other suitable structure. The solar modules 214 may correspond to photovoltaic solar cells that convert solar energy into electricity, or alternatively, solar heating or thermal modules which directly generate heat using solar energy. In an example, the solar modules 214 can be simply an insulated glass assembly consisting of two high reflectance glass panels with a low thermal conductivity material between the panels. Alternatively, the solar modules can be a combination of photovoltaic solar cells and thermal modules according to one or more embodiments.

According to one or more embodiments, the rail structures 212 are adjustable pair-wise, or in other combinations, in order to hold in place solar modules 214 of various dimensions and sizes. In one or more embodiments, the solar modules 214 are supported by a combination of retention structures 216. Each retention structure 216 may be provided with a corresponding one of the rail structures 212. In one or more embodiments, each retention structure 216 is a structural feature of the corresponding rail structure 212. For example, each rail structure 212 may comprise of multiple interconnected segments, and the retention structure(s) may be one of the interconnected elements. Alternatively, the retention structures 216 may be integrated or unitarily formed with the individual rail structures 212. Each retention structure 216 supports individual solar modules 214 by grasping edge segments. In one or more embodiments, the retention structures 216 and/or rail structures 212 are adjustable to grasp and support solar modules 214 of varying thicknesses and forms.

Referring again to FIG. 2, an embodiment provides that rail structures 212 are mounted indirectly to the roof 210 through use of a set of strut runners 218. Each strut runner 218 mounts to the roof 210 and to multiple rail structures 212, thus providing lateral support to maintaining the rail structures 212 upright, while at the same time providing a buffer between the individual rail structures 212 and the underlying body 215. The rail structures 212 may mount to the strut runners 218, and the strut runners may mount to the roof 210. The side view of FIG. 2 shows a cross section the structures along horizontal direction being parallel to the strut runners 218. The rail structures 212 are along the sloped (if any) direction and so do lengths of the channels 220.

According to an embodiment, combination of at least a portion of the one or more solar modules 214, a partial surface area of the roof structure 215, and the rail structures 212 provides some basic elements for forming a plenum structure 200. Additionally, the plenum structure 200 becomes part of a solar heat exchange system that uses heat generated from the solar modules 214 for any one of various useful purposes. The heat exchange may be enabled by the formation of one or more channels 220 between an underside of solar modules 214 and an upside of the underlying body 215. An individual channel 220 may be defined or enclosed in part by one or more of the rail structures 212, as well as partial surface areas of the underlying body and partial underside surface areas of the solar modules 214. The individual channel 220 may occupy at least a portion of the thickness defined by the height h. The plenum structure 200 further includes an opening region 217 for drawing cooler air into the channel 220 and an exhaust 219 for directing hotter air out of the channel for achieving the roof cooling. More features of the plenum structure can be found via schematic illustrations of FIGS. 2A and 2B below.

FIG. 2A is a schematic side view diagram of a plenum structure according to an embodiment of the present invention. This diagram is merely an example, which should not unduly limit the scope of the claims herein. One of ordinary skill in the art would recognize other variations, modifications, and alternatives. As shown, the plenum structure 200 includes a simple thermal module 214 made of an insulation glass assembly mounted on a surface region 211 of a roof 210. In a specific embodiment, the insulation glass assembly includes two high reflectance glass panels 221 and 223 with a low thermal conductivity material 225 between the panels. The glass panel 221 or 223 can be a regular window glass but with tempered treatment to enhance its strength to resist impact of foreign object such as hail. The low thermal conductivity material 225 can be nitrogen, or argon, or other inert gas or the likes. In an alternative embodiment, the thermal module 214 represents a fully assembled photovoltaic solar module which has an upper window glass 221 and a bottom glass substrate 223 and one or more solar cells formed in between. The solar cells can be poly-silicon based solar cells, or thin film absorber based solar cells, or any combinations of both types. The glass assembly is sealed or laminated surrounding edges of both panels by a structural element 227 and mounted through one or more retention structures or interconnected elements 216 to a rail structure 212. As shown, the rail structure 212 is along the sloped (if any) direction of the roof 210. For example, the label A indicates a relative lower region of the roof and B a relative upper region of the roof. The rail structure is mounted to the roof 210 through a strut runner 218 into the underlying body 215 by a pin element 219. The strut runner 218 is then in parallel to horizontal direction (into the view plane of FIG. 2A). An opening 217 is located at the lower end of the plenum structure for drawing cooler air from ambient. Optionally, an air director device 250 can be added there for enhancing fluid flow when necessary. Another opening 219 is located on upper region of the roof surface, which is designed for air exhaust for directing hot air (or fluid) out of the partial enclosed volume 220 of the plenum structure 200. In an embodiment, the opening 219 is coupled to a duct structure (not fully shown) which leads the hot air to a heat exchange/transfer module associated with the plenum structure.

In one or more embodiments, the plenum structure 200 is associated with the thermal solar system 100 of FIG. 1 which may further include other components, such as a plurality of thermal panels, as well as air directors that draw air into the channels 220, and/or push the air through the channels. When installed as part of a thermal solar system, the plenum structure 200 may be positioned to supply heated air to such air directors, and to be proximate to the environment that is to receive or use the heated air. For example, the plenum structure 200 may be installed on the rooftop of a dwelling, and also direct heated air into a vent or air circulation system of the dwelling as part of its ability to heat air in the enclosed volume or channel 220. Useful purposes for generating heat from the solar modules 214 may include, for example, any one or more of the following: (i) cooling the individual solar modules 214 (when they are photovoltaic cells) so as to make them more efficient, (ii) pulling air from the environment underneath the solar modules 214 for purpose of heating the air for another closed environment or system (e.g. for a house), and (iii) circulating air from the closed environment or system underneath the solar modules 214 to heat that air and use it for heat. Of course, there can be other variations, modifications, and alternatives.

FIG. 2B is a simplified perspective view diagram of a plenum structure associated with a thermal solar system according to an embodiment of the present invention. This diagram is merely an example, which should not unduly limit the scope of the claims herein. One of ordinary skill in the art would recognize other variations, modifications, and alternatives. As shown, the plenum structure 310, which is installed in association with a set of solar modules 314 covering at least a portion of surface area of an underlying body 315. The plenum structure 310 may be structured and adapted to include rack assembly features of plenum structure 200 described earlier with one or more embodiments of the invention. The underlying body 315 may correspond to, for example, a rooftop or roof structure of a building or dwelling. In general, the underlying body 315 may correspond to any area, surface or platform that can receive sunlight and be connected to a building, place or location that can use the solar energy.

Embodiments of the invention contemplate that different types of solar modules 314 may be employed in various implementations and context. For example, as shown by the simplified diagram of FIG. 2B, the solar modules 314 include photovoltaic modules 324 and thermal modules 325. The photovoltaic modules 324 can be made from cells based on pure/poly silicon pn junctions or thin-film semiconductor pn junction. The thermal modules 325 can be made specifically to absorb heat from sunlight. An example of the thermal module can be an insulated glass assembly comprising a double glass panels with a non-conductive material sealed in-between. Under one or more embodiments, the perimeter may include one or more sealed lengths 332 on two sides and upper edge and an open length 334 located at the lower edge. The open length 334 is substantially the same as the opening 217 in FIG. 2A, from which air from the environment is drawn into the channels. The channels or the volume enclosed by the solar modules and a portion of surface area of the underlying body and between a pair of rail structures of the rack assembly that are provided for purpose of constraining airflow. Air drivers and directors (not show) may drive (e.g. push or pull) air within the formed channels or re-direct to other regions through one or more ducts or pathways. The solar modules 314 generate heat, either through design or as an inherent by-product. According to one or more embodiments, this heat warms the air as it is drawn from the environment and pulled through the channels formed underneath the solar modules 314.

Numerous alternatives and variations are contemplated. For example, all of the perimeter of the plenum structure 310 may be sealed, and air may be drawn from interior of a dwelling or building structure beneath the underlying body 315 on which the rack assembly of the plenum structure 310 is provided. Then air may be pushed through channels, then back into the dwelling when warmed. Alternatively, some or all of the open length 334 may be sealed, or conversely, portions of the sealed lengths 132 may be opened or perforated as part of a channel. As shown, FIG. 2B illustrates an implementation in which heated air is directed into a duct 340 within a structure beneath the underlying body 315. For example, warm air may heat a dwelling on which the rack assembly of the plenum structure 310 is installed, and the duct 340 enables the heated air to flow into a circulation system of the dwelling. As mentioned, the solar modules 314 associated with the plenum structure 310 may be formed by a combination of the photovoltaic modules 324 and the thermal modules 325. The photovoltaic modules 324 can generate some residual heat when receiving solar energy and converting the solar energy into electrical current. In contrast, the thermal modules 325 may directly convert the solar energy into heat at a higher efficiency. The use and number of thermal modules 325 may depend on the use of the heated airflow, as well as the environment where the plenum structure 310 is installed. For example, when the purpose of heating air in the channels is to supply warm air to a dwelling of the underlying body 315, the thermal modules 325 have more use in colder environments, while warm environments may require only use of photovoltaic modules 324. Even in cold environments, thermal modules 325 may be used to convert solar energy into hot air due to the high operating efficiency achieved by their designs, and additional components may be used to drive the hot air into the dwelling.

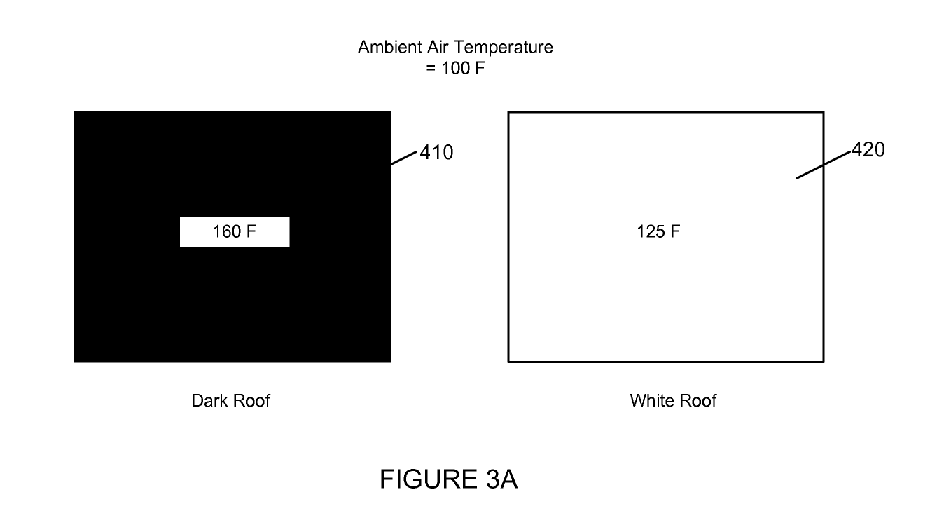

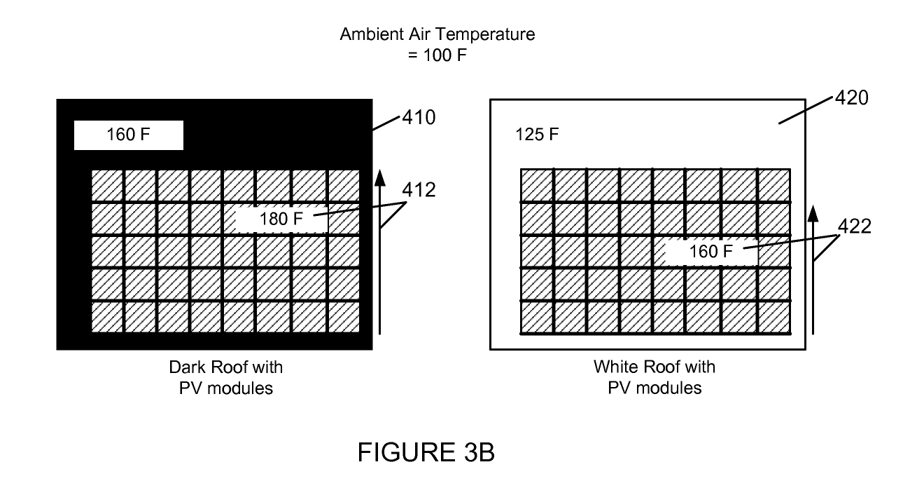

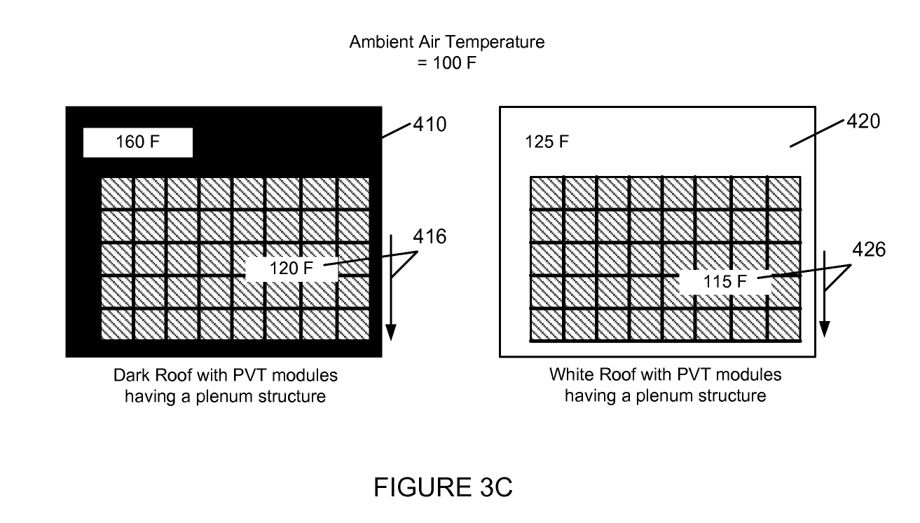

One or more embodiments of the present invention with and the roof cooling advantages using a plenum structure over conventional roof with or without a solar energy system installed can be further illustrated by several examples shown below. FIG. 3A is a simplified view of a section of dark roof versus a section of white roof in ambient air under the sun. A dark roof refers to a roof with a surface region 410 that substantially absorbs the incident sun light and transfer to heat. In a sunny day with ambient air temperature of about 100 degrees Fahrenheit, the surface temperature of the dark roof can be reached to about 160 Degree Fahrenheit or greater. If the roof is treated to become a cooled white roof with some portion of incident light being reflected, then the surface region 420 of the white roof can have its surface temperature lowered to about 125 degrees Fahrenheit under the same ambient condition.

Assuming that a solar energy system, for example a conventional PV system including a N×M matrix of modules, is installed respectively on these roofs, as shown in FIG. 3B. The PV system does its work to convert sun light (at least partially) to electric power, while it also generates a substantial amount of heat. Part of the heat is absorbed by each PV module itself and at least a portion of the heat is released to the air below the PV system which drives the surface temperature of the roof (the spatial region covered by the PV system) much higher. Arrow 412 is used to indicate the roof temperature increase caused by the PV system installed over a surface region on the dark roof 410. This is also true for the case with white roof 420, where arrow 422 is referred to corresponding temperature increase of the roof surface region covered by the PV system installed thereon. However, the conventional PV system neither utilizes such the portion of the heat, nor prevents such heat from inducing some bad side effects to both the PV system itself and the dwellings on which the PV system is installed. After replacing the conventional PV system with a PVT system having a plenum structure (underneath the PVT panel), the roof temperature can decrease, instead of increase, to form a cool roof. In addition, the portion of heat can be effectively utilized or stored for many other applications. As shown in FIG. 3C, the dark roof and the white roof each has a PVT system with a plenum structure installed according to an embodiment of the present invention. Arrow 416 represents a lowered roof temperature (compared to bare dark roof surface) with the PVT system having the plenum structure installed. Similarly, arrow 426 also represents a lowered roof temperature (compared to bare white roof surface) with a PVT system having the plenum structure installed. More details of the roof temperature profiles associated with the plenum structure using air flow control can be found below and throughout the specification.

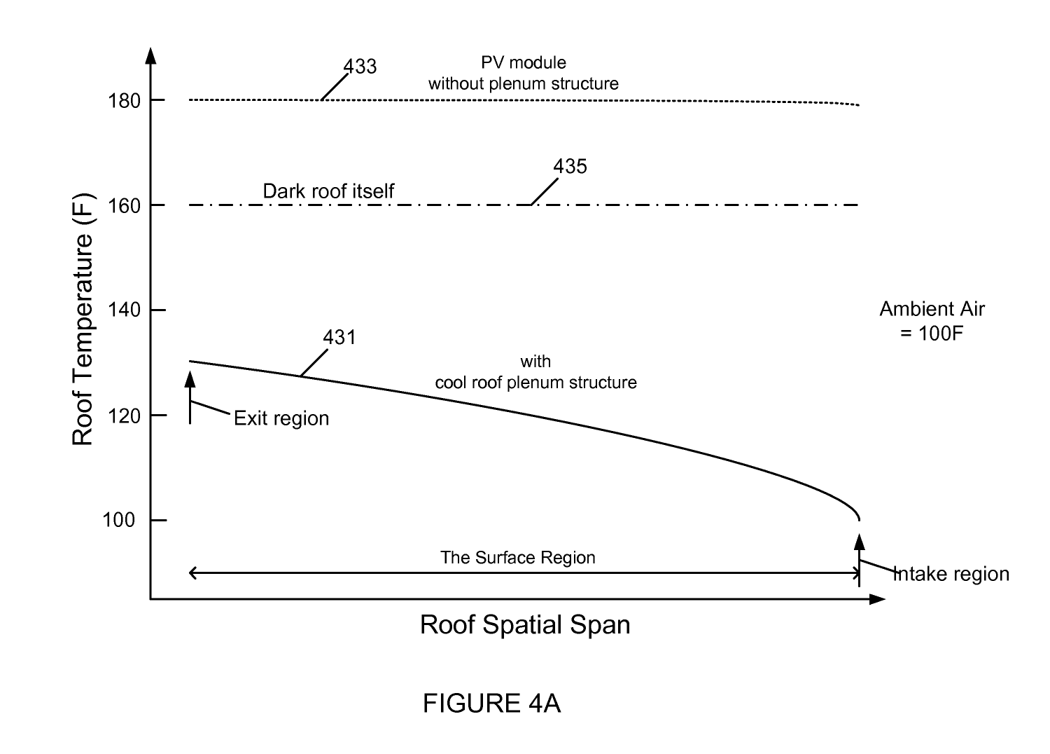

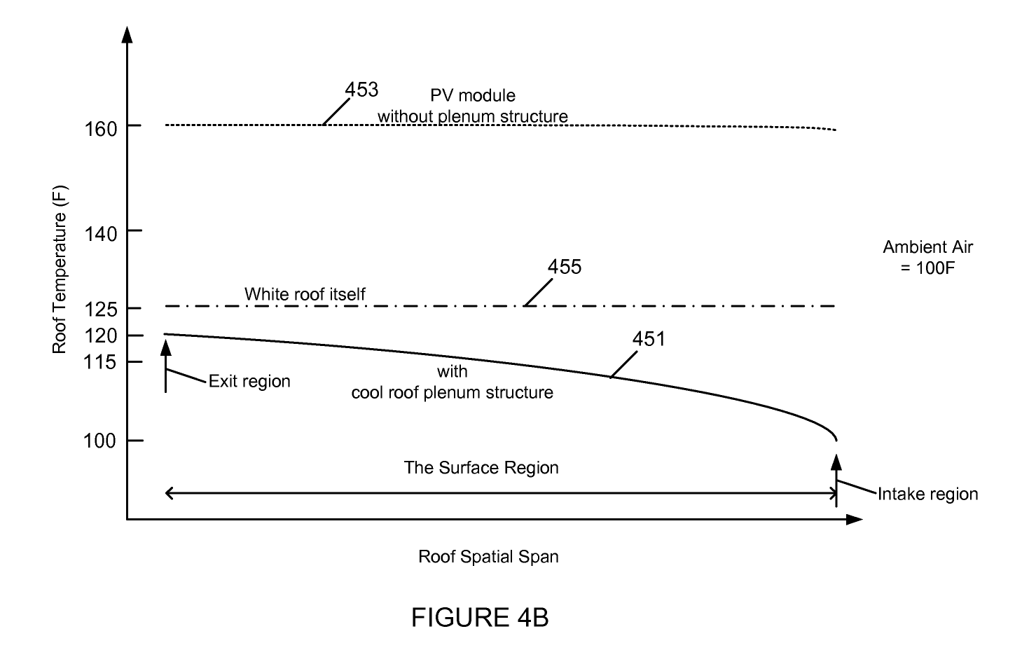

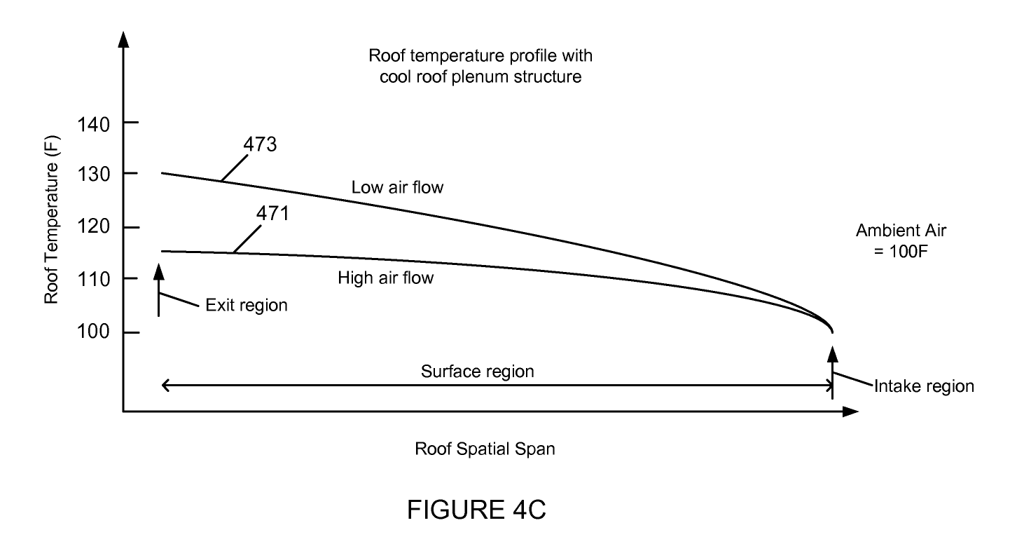

FIG. 4A shows simplified roof temperature profiles for dark roof with and without a plenum structure according to an embodiment of the present invention. This diagram is merely an example, which should not unduly limit the scope of the claims herein. One of ordinary skill in the art would recognize other variations, modifications, and alternatives. As shown, a dark roof (for example, dark roof 410 in FIG. 3A) is exposed under the sun with an ambient air temperature of about 100 degrees Fahrenheit. By itself, the roof temperature can reach to about 160 degrees Fahrenheit, as indicated by curve 435.

If the roof has a conventional PV module installed on a portion of surface area, without a plenum structure to transfer the heat generated by the PV module, the roof temperature can be increased quickly across the spatial area. In a specific embodiment, even though the PV module covers the surface so that at least near an intake region the roof temperature may be lowered (compared to bare roof under the sun), most portions of the surface area have higher temperature compared to bare roof, because of a substantial amount of heat is generated from the PV module that heat the air between the PV module and the roof surface. Curve 433 provides an example of the temperature profile for this case, which shows a maximum temperature can be as high as 180 degrees Fahrenheit.

In another embodiment, if a plenum structure is added to the conventional PV module, the temperature profile is represented by curve 431 across the same spatial surface area from an air intake region (of the plenum structure) to an air exit region of the plenum structure. In a specific embodiment, the plenum structure can be the same as plenum structure 310 shown in FIG. 2B, with intake region 324 and exit region 340. As shown in FIG. 4A, the roof temperature is actually reduced compared to a bare roof under the sun, due to the plenum structure using at least a flow rate of the air between the PV module and roof surface. On average, the roof temperature is only about 120 degrees Fahrenheit (maximum at about 130 degrees Fahrenheit). Of course, there are many variations, alternatives, and modifications in PV module, roof structure, installation details, and air flow rate variations. One of ordinary skilled in the art should recognize that the above illustration does not unduly limit the scope of the claims herein. For example, a PVT system may include both PV solar module and thermal solar module, and each type alone, or any other combinations. The corresponding temperature profile may have different slope or curvature or maximum point depending on the length of the module, the plenum structure layout, the air flow rate, etc. In a specific embodiment, the maximum roof temperature in the plenum structure can be maintained about 20 degrees Fahrenheit or less above ambient air temperature, which is well below (or being cooled from) possible roof temperature of a bare roof surface under the sun.

FIG. 4B shows simplified roof temperature profiles for white roof with and without a plenum structure according to an embodiment of the present invention. This diagram is merely an example, which should not unduly limit the scope of the claims herein. One of ordinary skill in the art would recognize other variations, modifications, and alternatives. As shown, a cool white roof (for example, white roof 420 in FIG. 3A) is exposed under the sun with an ambient air temperature of about 100 degrees Fahrenheit. By itself, the roof temperature can reach to about 125 degrees Fahrenheit, as indicated by curve 455. Curve 453 represents the white roof having a conventional PV module installed without the plenum structure. Apparently, the roof temperature is much greater than the bare roof on most portion of the roof surface area covered by the PV module. Curve 451 represents the same white roof having a plenum structure installed to drive air flow between the PV module panel and roof surface. As the result, the whole roof temperature becomes lower than the bare roof, achieving a cool roof function according to one or more embodiments of the present invention. In an example, at ambient air temperature of about 100° F., the white roof can be heated to about 125° F., while a (portion of) cool roof using plenum structure according to an embodiment of the present invention can be only 120° F. at most or only about 115° F. on average across the whole covered surface area. In an embodiment, the maximum roof temperature within the plenum structure can be maintained about 20 degrees Fahrenheit or less above ambient air temperature, which is well below (or being cooled from) possible roof temperature of a bare roof surface under the sun. Of course, there can be other variations, modifications, and alternatives.

FIG. 4C shows simplified roof temperature profiles of a cool roof plenum structure respectively with high and low air flow rate according to an embodiment of the present invention. This diagram is merely an example, which should not unduly limit the scope of the claims herein. One of ordinary skill in the art would recognize other variations, modifications, and alternatives. As shown, a curve 471 represents a roof temperature profile across the spatial region of the surface area covered by a cool roof plenum structure driving the air in a relative high flow rate from an intake region of the plenum structure to an exit region. This temperature profile is compared with another curve 473 representing a roof temperature profile of the same system with a relative low air flow rate. In an embodiment, the cool roof plenum structure can use at least the air flow rate to control the roof temperature to a desired result for a specific roof structure on which the cool roof plenum structure is installed. Of course, there can be other variations, modifications, and alternatives. For example, the flow rate of the volume of air in the plenum structure being transferred for maintaining the roof temperature profiles can range from zero to about 200 cubic feet per minute and greater. Depending on the application, an optimum flow rate can always be selected for a specific plenum structure installment, aiming for achieving greatest possible reduction of in roof cooling energy with a lowest usage in power for driving the air flow. Therefore, an optimal operation of a cool roof plenum structure can be performed in a well-controlled manner, providing highest possible overall energy conversion efficiency of more than 30%. Here the term “high” or “low” flow rates merely refers to its actual meaning when both are compared together and do not intend to define a particular range as high or low.

Although the above has been described in terms of a cool roof method and system, other alternatives, variations, and modifications can exist. As an example, the method and system can be used to provide thermal energy to a roof, thereby heating it, as well as cooling the roof in one or more embodiments. In one or more embodiments, the present method and system emits infrared radiation, and possibly other forms of radiation. Of course, there can be other variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for cooling a roof by processing fluid within a vicinity of a roof structure, the method comprising, on a roof structure having a surface area:
transferring a volume of air with a selected flow rate through a plenum structure disposed underlying at least one solar module and coupled to the roof structure spatially over a height above a portion of the surface area, the plenum structure having at least an intake region and an exit region for the volume of air; and
maintaining a roof temperature profile for the portion of the surface area starting from the intake region to the exit region for a predetermined amount of time using at least the flow rate of the volume of air being transported through the plenum structure;
wherein the roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

2. The method of claim 1 wherein the roof temperature profile within the portion of the surface area comprises an average temperature no greater than about 105 degrees Fahrenheit on a day with 90 degrees Fahrenheit ambient air temperature.

3. The method of claim 1 wherein the second temperature value is a less than 20 degrees Fahrenheit above the first temperature value.

4. The method of claim 1 wherein the plenum structure comprises an upper surface region composed of at least a portion of the one or more solar modules and a lower surface region composed of the portion of the surface area of the roof structure.

5. The method of claim 1 wherein the plenum structure is characterized by one or more channels with a flow length of greater than about six feet, each of the one or more channels having a pair of sidewalls composed by a portion of a rail structure for supporting the one or more solar modules.

6. The method of claim 1 wherein the flow rate of the volume of air being transferred for maintaining the roof temperature profile ranges from zero to about 200 cubic feet per minute and greater.

7. The method of claim 1 wherein the transferring a volume of air comprises using a fluid drive device coupled to the plenum structure.

8. The method of claim 7 wherein the fluid drive device is configured to cause at least a portion of the volume of air to flow from ambient through the intake region to an interior of a building structure underlying the roof structure through the exit region.

9. The method of claim 7 wherein the fluid drive device is configured to cause at least a portion of the volume of air to vent back to ambient or flow to an air circulation system.

10. The method of claim 7 wherein the fluid drive device comprises one or more turbulation elements controlled by a controller to adjust the flow rate and a flow direction.

11. The method of claim 1 wherein the one or more solar modules comprise at least a thermal module made from an insulated glass assembly comprising two high reflectance glass panels with a low thermal conductivity material between the panels.

12. The method of claim 11 wherein the insulated glass assembly is capable of withstanding winds of up to 100 mph.

13. The method of claim 11 where the glass panels use tempered glass capable of resisting foreign objects such as hail.

14. The method of claim 1 wherein the one or more solar modules comprise at least a photovoltaic solar module or a combination of one or more thermal modules and one or more photovoltaic solar modules.

15. The method of claim 1 wherein when there is no air movement between the upper surface region and lower surface region and the stagnant air acts as an insulator and prevents the lower surface region of the plenum structure from attaining excessive heat.

16. A system for providing a roof maintained within a predetermined temperature range by processing fluid within a vicinity of a roof structure, the system comprising:
a roof structure having a surface area;
a plenum structure configured for transferring a volume of air within a selected flow rate, the plenum structure being disposed underlying one or more solar modules and coupled to the roof structure spatially over a height above a portion of the surface area, each of the one or more solar modules being coupled to each other, the plenum structure having at least an intake region and an exit region for the volume of air; and
a roof temperature profile configured within the portion of the surface area starting from the intake region to the exit region for a predetermined amount of time using at least the flow rate of the volume of air being transported through the plenum structure;
wherein the roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

17. A system for providing a roof maintained within a predetermined temperature range by processing fluid within a vicinity of a roof structure, the system comprising:
a plenum structure configured for transferring a volume of air within a selected flow rate, the plenum structure coupled to a roof structure spatially over a height above a portion of a surface area of the roof structure, the plenum structure having at least an intake region and an exit region for the volume of air; and
a roof temperature profile configured within the portion of the surface area starting from the intake region to the exit region for a predetermined amount of time using at least the flow rate of the volume of air being transported through the plenum structure, the roof temperature profile being configured by a first temperature value substantially equal to an ambient air temperature at the intake region to a second temperature value in the vicinity of the exit region depending on the flow rate and substantially smaller than a temperature of bare roof structure outside the portion of the surface area.

18. A method for providing a roof within a predetermined temperature range by processing fluid within a vicinity of a roof structure, the method comprising:
transferring a volume of air with a selected flow rate through a plenum structure coupled to a roof structure spatially over a height above a portion of the surface area, the plenum structure having at least an intake region and an exit region for the volume of air; and
maintaining a roof temperature profile for the portion of the surface area starting from the intake region to the exit region for a predetermined amount of time using at least the flow rate of the volume of air being transported through the plenum structure;
wherein the roof temperature profile comprises a first temperature value substantially equal to an ambient air temperature at the intake region to a second temperature value in the vicinity of the exit region depending on the flow rate and substantially smaller than a temperature of bare roof structure outside the portion of the surface area.

19. The method of claim 18 wherein the roof temperature profile within the portion of the surface area comprises an average temperature no greater than about 105 degrees Fahrenheit on a day with 90 degrees Fahrenheit ambient air temperature.

20. The method of claim 18 wherein the second temperature value is a less than 20 degrees Fahrenheit above the first temperature value.

21. The method of claim 18 further comprising emitting infrared radiation from the roof structure or plenum structure.

22. The method of claim 18 wherein the roof structure is white in color.

23. A method for providing a cool roof by processing fluid within a vicinity of a roof structure, the method comprising:
providing a roof structure having a surface area; and
maintaining a temperature profile for a portion of the surface area starting from an intake region to an exit region for a predetermined amount of time using at least a flow rate of a volume of air being transported through a plenum structure configured within a vicinity of the portion of the surface area.

24. A thermal solar system for providing a roof maintained within a predetermined temperature range, the system comprising:
a plenum structure configured for transferring a volume of air within a flow rate, the plenum structure coupled to a surface region of a roof structure; and
a temperature profile configured within the portion of the surface area starting from a first region to a second region of the plenum structure for a predetermined amount of time using at least the flow rate of the volume of air being transported through the plenum structure.
